(19) United States
(12) Patent Application Publication
(10) Pub. No.: US 2026/0045462 A1
(43) Pub. Date: Feb. 12, 2026

(54) COMPENSATING FOR PARAMETER DISCREPANCIES CAUSED BY MATCHING CIRCUITS IN A MULTI-FEED SYSTEM

(71) Applicant: ASM IP Holding B.V., Almere (NL)

(72) Inventors: Ronald Anthony Decker, Turnersville, NJ (US); Jordan Alexander Thimot, Philadelphia, PA (US); Matthew Rassmann, Marlton, NJ (US)

(21) Appl. No.: 19/293,935

(22) Filed: Aug. 7, 2025

Related U.S. Application Data
(60) Provisional application No. 63/681,970, filed on Aug. 12, 2024.

(51) Int. Cl. H01J 37/32

(52) U.S. Cl. CPC H01J 37/32926; H01J 37/32183; H01J 37/3299

(57) ABSTRACT

In one embodiment, the present disclosure is directed to a system for providing energy to a plasma chamber having multiple power signal inputs. A power source transmits output signals to matching circuits. Each of the matching circuits provides different match positions. A memory stores, for each match position of each matching circuit, and for each output signal, parameter discrepancy data for a parameter, such as power or phase, of the output signal at an output of the matching circuit. For each of the matching circuits and its corresponding output signal, the control circuit causes the power source to alter the parameter based on the parameter discrepancy data, the alteration of the parameter preventing or decreasing the anticipated discrepancy between the desired value for the parameter and the actual value for the parameter.

### BACKGROUND

Multi-feed plasma chambers for semiconductor processing applications benefit from accurate, repeatable, and uniform power delivery. Such power delivery may be compromised, however, by unintended power loss and phase shifting caused by impedance matching circuits, which are used to impedance match between the power source and the plasma chamber.

### BRIEF SUMMARY

The present disclosure may be directed, in one aspect, to a system comprising a power source transmitting output signals via power source outputs; matching circuits coupled to the power source outputs, each matching circuit configured to receive a single corresponding output signal of the output signals; comprising at least one variable network element, each variable network element having different configurations providing different match positions; and configured to couple to a plasma chamber; a memory configured to store, for each match position of each matching circuit, and for each output signal, parameter discrepancy data for a parameter of the output signal; wherein the parameter is related to a power or a phase of the output signal at an output of the matching circuit or at an input of the plasma chamber; and wherein the parameter discrepancy data is related to an anticipated discrepancy between a desired value for the parameter and an actual value of the parameter; and a control circuit configured to, for each matching circuit and its corresponding output signal, cause the power source to alter the parameter of the output signal based on the parameter discrepancy data for the match position corresponding with a current match position for the matching circuit, the alteration of the parameter of the output signal directed to preventing or decreasing the anticipated discrepancy between the desired value for the parameter and the actual value for the parameter.

In another aspect, a method of providing energy to a plasma chamber having multiple power signal inputs is disclosed, the method comprising transmitting output signals to matching circuits such that each matching circuit receives a single corresponding output signal of the output signals; wherein each of the matching circuits comprises at least one variable network element, each variable network element having different configurations providing different match positions, and coupling each matching circuit to a plasma chamber; storing, for each match position of each matching circuit, and for each output signal, parameter discrepancy data for a parameter of the output signal; wherein the parameter is related to a power or a phase of the output signal at an output of the matching circuit or at an input of the plasma chamber; and wherein the parameter discrepancy data is related to an anticipated discrepancy between a desired value for the parameter and an actual value of the parameter; and for each matching circuit and its corresponding output signal, causing the power source, during operation of the system, to alter the parameter of the output signal based on the parameter discrepancy data for the match position corresponding with a current match position for the matching circuit, the alteration of the parameter of the output signal directed to preventing or decreasing the anticipated discrepancy between the desired value for the parameter and the actual value for the parameter.

In another aspect, a system comprises matching circuits configured to couple to a power source, each matching circuit configured to receive a corresponding output signal from the power source; comprising at least one variable network element, each variable network element having different configurations providing different match positions; and configured to couple to a plasma chamber; a memory configured to store, for each match position of each matching circuit, and for each output signal, parameter discrepancy data for a parameter of the output signal; wherein the parameter is related to a power or a phase of the output signal at an output of the matching circuit or at an input of the plasma chamber; and wherein the parameter discrepancy data is a value based on a difference between a desired value for the parameter and an actual value for the parameter; and a control circuit configured to, for each matching circuit and its corresponding output signal, cause the power source to alter the parameter of the output signal based on the parameter discrepancy data for the match position corresponding with a current match position for the matching circuit, the alteration of the parameter of the output signal directed to preventing or decreasing the anticipated discrepancy between the desired value for the parameter and the actual value for the parameter.

While the disclosed inventions are applicable to semiconductor fabrication systems, the invention is not so limited.

### BRIEF DESCRIPTION OF THE DRAWINGS

The present disclosure will become more fully understood from the detailed description and the accompanying drawings, wherein:

FIG. 1 is a schematic of a system for fabricating a semiconductor according to one embodiment.

FIG. 2 is a block diagram of a power source according to one embodiment.

FIG. 3 is a matching circuit according to one embodiment.

FIG. 4 is an electronically variable capacitor according to one embodiment.

FIG. 5 is schematic of a first microstrip-based variable network element according to one embodiment.

FIG. 6 is schematic of a second microstrip-based variable network element according to one embodiment.

FIG. 7 is a flowchart for a method of providing energy to a plasma chamber having multiple power signal inputs according to one embodiment.

The drawings represent one or more embodiments of the present invention(s) and do not limit the scope of invention.

### DETAILED DESCRIPTION

The following description of the preferred embodiment(s) is merely exemplary in nature and is in no way intended to limit the invention or inventions. The description of illustrative embodiments is intended to be read in connection with the accompanying drawings, which are to be considered part of the entire written description. The discussion herein describes and illustrates some possible non-limiting combinations of features that may exist alone or in other combinations of features. Furthermore, as used herein, the term “or” is to be interpreted as a logical operator that results in true whenever one or more of its operands are true. Furthermore, as used herein, the phrase “based on” is to be interpreted as meaning “based at least in part on,” and therefore is not limited to the interpretation “based entirely on. ” Furthermore, the term “each,” when used in reference to each of a plurality of items, need not refer to each such item in an entire system or apparatus, but may instead simply refer to each of the recited one or more such items in the system.

As used throughout, ranges are used as shorthand for describing each and every value that is within the range. Any value within the range can be selected as the terminus of the range. In addition, all references cited herein are hereby incorporated by referenced in their entireties. In the event of a conflict in a definition in the present disclosure and that of a cited reference, the present disclosure controls.

In the following description, where block diagrams or circuits are shown and described, one of skill in the art will recognize that, for the sake of clarity, not all peripheral components or circuits are shown in the figures or described in the description. For example, common components such as memory devices and power sources may not be discussed herein, as their role would be easily understood by those of ordinary skill in the art. Further, the terms “couple” and “operably couple” can refer to a direct or indirect coupling of two components of a circuit.

It is noted that for the sake of clarity and convenience in describing similar components or features, the same or similar reference numbers may be used herein across different embodiments or figures. This is not to imply that the components or features identified by a particular reference number are identical across each embodiment or figure, but only to suggest that the components or features are similar in general function or identity.

Features of the present inventions may be implemented in software, hardware, firmware, or combinations thereof. The computer programs described herein are not limited to any particular embodiment, and may be implemented in an operating system, application program, foreground or background processes, driver, or any combination thereof. The computer programs may be executed on a single computer or server processor or multiple computer or server processors.

Processors described herein may be any central processing unit (CPU), microprocessor, micro-controller, computational, or programmable device or circuit configured for executing computer program instructions (e.g., code). Various processors may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage such as volatile and non-volatile memory, input/output devices, graphical user interfaces (GUIs), removable data storage, and wired and/or wireless communication interface devices including Wi-Fi, Bluetooth, LAN, etc. As used herein, the term “processor”may refer to one or more processors.

Computer-executable instructions or programs (e.g., software or code) and data described herein may be programmed into and tangibly embodied in a non-transitory computer-readable medium that is accessible to and retrievable by a respective processor as described herein which configures and directs the processor to perform the desired functions and processes by executing the instructions encoded in the medium. A device embodying a programmable processor configured to such non-transitory computer-executable instructions or programs may be referred to as a “programmable device”, or “device”, and multiple programmable devices in mutual communication may be referred to as a “programmable system. ” It should be noted that non-transitory “computer-readable medium” as described herein may include, without limitation, any suitable volatile or non-volatile memory including random access memory (RAM) and various types thereof, read-only memory (ROM) and various types thereof, USB flash memory, and magnetic or optical data storage devices (e.g., internal/external hard disks, floppy discs, magnetic tape CD-ROM, DVD-ROM, optical disk, ZIP™ drive, Blu-ray disk, and others), which may be written to and/or read by a processor operably connected to the medium.

In certain embodiments, the present inventions may be embodied in the form of computer-implemented processes and apparatuses such as processor-based data processing and communication systems or computer systems for practicing those processes. The present inventions may also be embodied in the form of software or computer program code embodied in a non-transitory computer-readable storage medium, which when loaded into and executed by the data processing and communications systems or computer systems, the computer program code segments configure the processor to create specific logic circuits configured for implementing the processes.

### Semiconductor Processing System

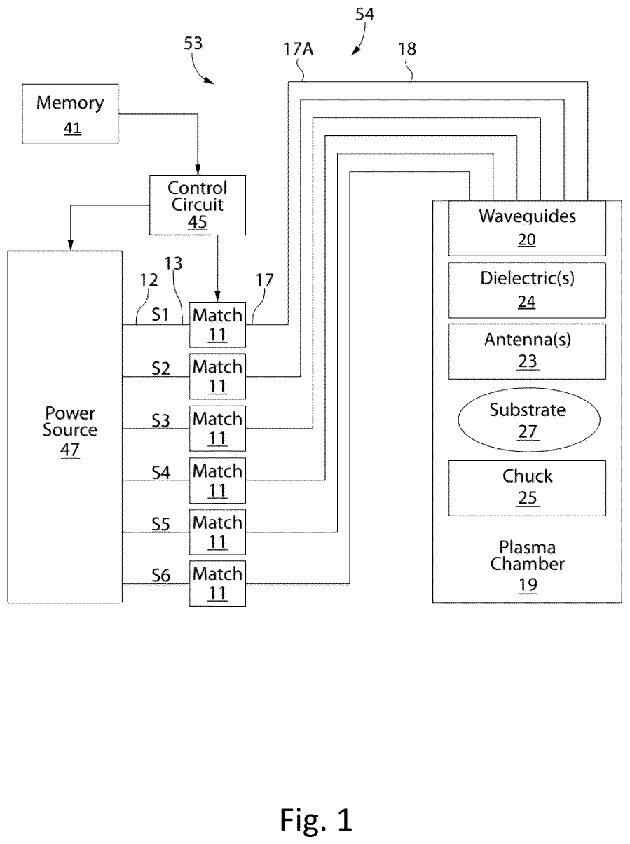

Referring now to the figures, FIG. 1 is a schematic of a system 53 for fabricating a semiconductor according to one embodiment, the system 53 including a system 54 for providing energy to a plasma chamber 19 having multiple power signal inputs. The system 54 includes a power source 47. The exemplified power source 47 transmits, via power source outputs 12, power signals S1-S6 to the plasma chamber 19.

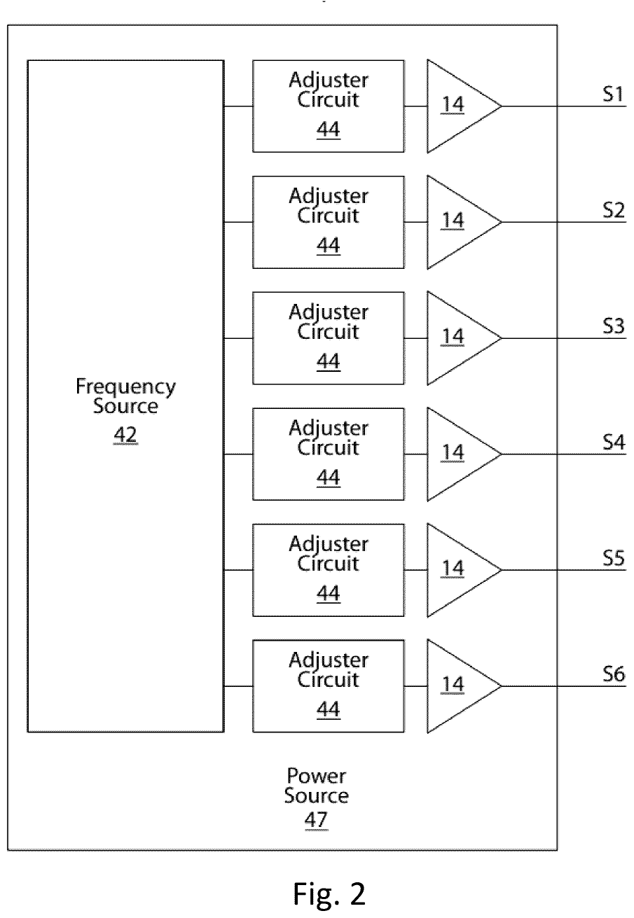

FIG. 2 is a block diagram of a power source 47 according to one embodiment. The exemplified power source 47 includes a frequency source 42 for providing initial signals that are fed to adjuster circuits 44. The adjuster circuits are configured to adjust the phase and/or magnitude of the initial signals. One or more amplifiers 14 may amplify the adjusted signals. Other potential components, such as filters, are not shown. The output signals S1-S6 of the power source 47 are provided to the plasma chamber by a conductor 17A (FIG. 1), such as a coaxial connector (which may or may not include a coaxial cable). It is noted that the invention is not limited to the exemplified power source 47. For example, the adjuster circuits 44 may be separate from the power source 47, or may be a single circuit. In yet other embodiments, the power source 47 may comprise a plurality of discrete power sources.

Returning to FIG. 1, exemplified plasma chamber 19 includes waveguides 20 that receive the power signals S1-S6. The exemplified waveguides 20 provide the signals S1-S6 to one or more dielectrics 24 providing energy to the one or more antennas 23 of the plasma chamber 19. The plasma chamber 19 includes a chuck 25 for holding the substrate. In processes known in the art, the first antenna(s) 23 and the chuck 25, in conjunction with appropriate control systems (not shown) and the plasma in the plasma chamber 19, enable deposition of materials onto a substrate 27 and/or etching of materials from the substrate 27 to fabricate a semiconductor device. The fabricated semiconductor device can be a microprocessor, a memory chip, or other type of integrated circuit or device. The invention is not limited to the exemplified plasma chamber.

In this embodiment, the antenna(s) 23 receives energy from the power source 47, while chuck 25 is ceramic and holds the substrate 27 and/or provides electrostatic (ESC) functionality. The one or more antennas 23 may be, for example, one or more slot antennas. The antenna may be made of a variety of conductive materials, such as aluminum or copper.

Plasma processing involves energizing a gas mixture by imparting energy to the gas molecules by introducing RF energy into the gas mixture. This gas mixture is contained in a vacuum chamber (the plasma chamber 19), and the RF energy is introduced into the plasma chamber 19 via the antenna(s) 23. Thus, the plasma may be energized by coupling power from the power source 47 into the plasma chamber 19 to perform deposition or etching. In certain plasma processes, the power source 47 generates power at a radio frequency and this power from the power source 47 is transmitted through cables 17A to the plasma chamber 19. In certain other plasma processes, a microwave frequency is used, such as 2.45 GHz, or 2-3 GHz, or at least 300 MHz, or at least 800 MHz. The invention is not so limited to one particular plasma process.

Co-owned U.S. Pat. No. 18,673,736 is incorporated by reference in its entirety. This application discloses a system and method for distributing energy to one or more antennas of a plasma chamber having multiple power signal inputs using circular waveguides evenly spaced azimuthally around a center point. The signals provided to the inputs of the plasma chamber are phase adjusted in a manner to enable the generation of circular polarization and improved electric field uniformity. The invention, however, is not limited to such a system or method.

The exemplified system 54 further includes a control circuit 45. The control circuit may receive inputs and provide instructions to components such as the power source 47, a memory 41, and the matching circuits 17. Co-owned U.S. Pub. No. 2023/0215696 is incorporated by reference in its entirety. The functionality of the control circuits described therein may similarly apply to control circuit 45. The control circuit and memory 41 will be described in further detail below in the discussion of compensating for parameter discrepancy.

In the exemplified embodiment, the control circuit 45 includes a processor. The processor may be any type of properly programmed processing device, such as a computer or microprocessor, configured for executing computer program instructions (e.g., code). The processor may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage such as volatile and non-volatile memory, input/output devices, graphical user interfaces (GUIs), removable data storage, and wired and/or wireless communication interface devices including Wi-Fi, Bluetooth, LAN, etc. The processor of the exemplified embodiment is configured with specific algorithms to enable it to perform the functions described herein.

### Matching Circuits

The system 54 further includes matching circuits 11 coupled to the power source outputs 12 such that each of the matching circuits 11 receives a single corresponding one of the output signals. The impedance matching circuit 11 helps maximize the amount of power transferred from the power source 47 to the plasma chamber 19 by matching the impedance at the input 13 to the impedance of the power source 47. The matching circuit 11 can consist of a single module within a single housing designed for electrical connection to the source 47 and plasma chamber 19. In other embodiments, the components of the matching circuit 11 can be located in different housings, some components can be outside of the housing, and/or some components can share a housing with a component outside the matching circuit.

As is known in the art, the plasma within a plasma chamber 19 typically undergoes certain fluctuations outside of operational control so that the impedance presented by the plasma chamber 19 is a variable impedance. Since the variable impedance of the plasma chamber 19 cannot be fully controlled, an impedance matching circuit may be used to create an impedance match between the plasma chamber 19 and the source power 47.

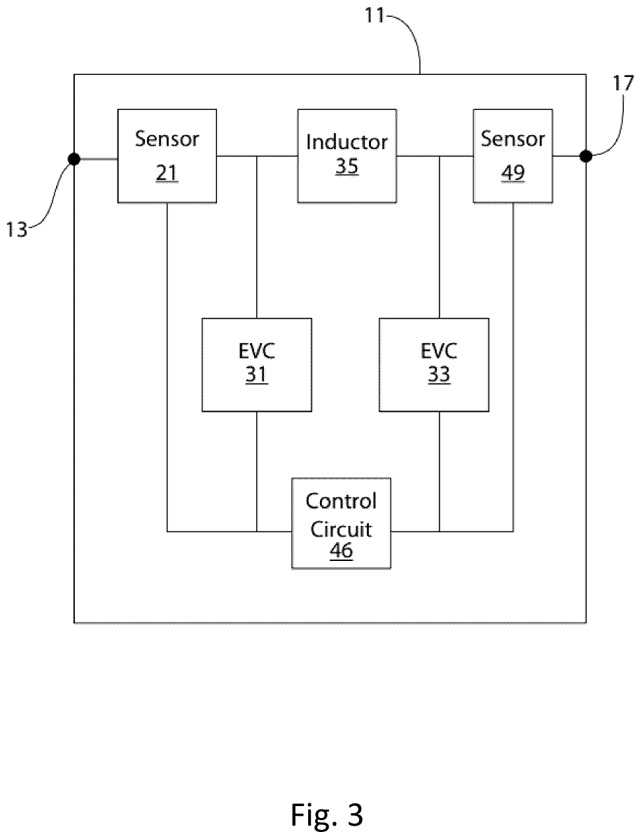

A block diagram of an example matching circuit 11 is shown in FIG. 3. The exemplified matching circuit 11 has an input 13 configured to couple to a power source and an output 17 configured to couple to a plasma chamber. The matching circuit 11 or system 54 may include an input sensor 21 coupled between the impedance matching circuit 11 and the power source 47. The matching circuit 11 or system 54 may also include an output sensor 49 coupled between the impedance matching circuit 11 and the plasma chamber 19, for example, so that the output from the impedance matching circuit, and the plasma impedance presented by the plasma chamber 19, may be monitored. The matching circuit 11 may include its own control circuit 46, or it may rely on an external control circuit such as control circuit 45 shown in FIG. 1

The matching circuit 11 of FIG. 3 is a “pi” type matching circuit, utilizing two shunt electronically variable capacitors (EVCs) 31, 33, and a series inductor 35, but the invention is not limited to a particular type of matching circuit. Co-owned U.S. Pub. No. 2023/0215696, which is incorporated by reference in its entirety, discusses a variety of potential matching networks, EVCs, and other variable elements.

### Variable Network Elements

EVCs 31, 33 are examples of variable network elements. As used herein, the term “variable network element” refers to any electrical component having different configurations that enable the matching circuit to provide different impedances, and thus enable the matching circuit to provide different match positions for providing impedance matches.

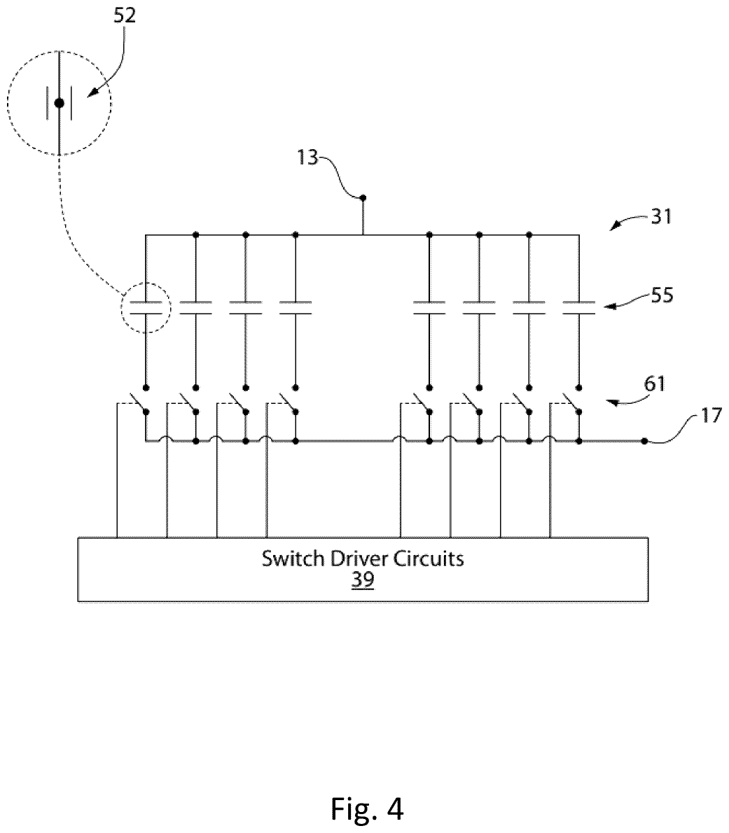

In FIGS. 3 and 4, the variable network element is an EVC 31, 33. As shown in FIG. 4, the exemplified EVC 31 comprises a plurality of discrete capacitors 55 (a type of reactance element) that are each switched in and out of the matching circuit 11 by corresponding switches 61 to provide different capacitances (reactances). The switches 61 can be PIN or NIP diodes, MOSFETs, JFETs, or another type of switch. The switches 61 may be coupled to switch driver circuits 39 for driving the switches on and off. The driver circuit 39 can receive instructions from control circuit 45 or 46, the control circuit instructing the EVCs (or other variable network elements) to take the match position best suited for providing an impedance match at a given point time. The driver circuit 39 can also utilize a choke and filter.

The invention, however, is not limited to the use of EVCs or capacitors. In other embodiments, the variable network element may comprise, for example, a plurality of discrete striplines or microstrips switched in and out to enable different match positions. In yet other embodiments, the discrete elements of the variable network element may comprise other transmission lines, or inductors.

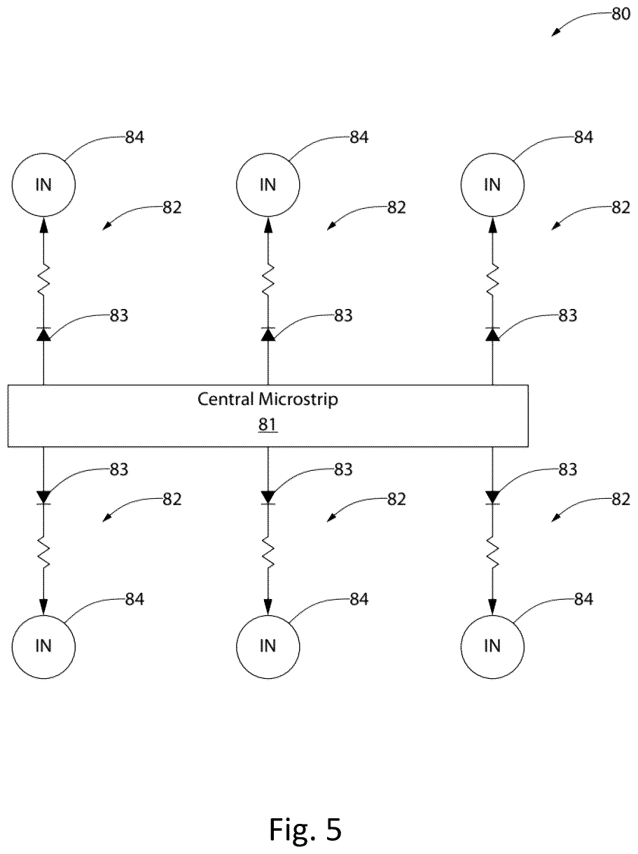

FIG. 5 is a schematic of a first microstrip-based variable network element 80 according to one embodiment. The first exemplified variable network element 80 comprises open-circuit microstrip stubs 82 that may be switched in and out of the circuit. The stubs 82 may have different lengths that provide different reactance amounts. The first exemplified element 80 has six stubs 82, but the invention is not so limited. Each stub 82 comprises a switch 83, which in this embodiment is a PIN diode 83 whose cathode is coupled (e.g., by ribbon bonding) to a central microstrip 81. An RF filter may be coupled between each diode 83 and the central microstrip 81. At nodes 84, each stub 82 is coupled to a driver circuit (not shown) that can forward or reverse bias the diode 83 to turn the diode 83 ON or OFF, and thus switch the corresponding stub 82 in or out of the circuit to enable the first variable network element 80 to provide varying total reactances. As discussed above, in other embodiments, the variable network element may vary its reactance by other means.

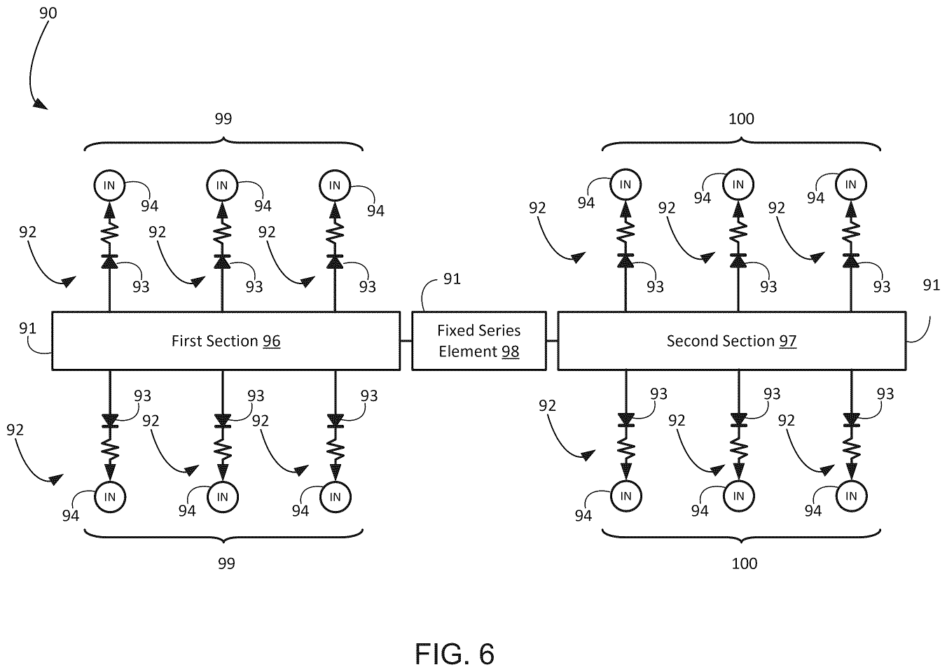

FIG. 6 is a schematic of a second microstrip-based variable network element 90 according to one embodiment. The second exemplified variable network element 90 comprises open-circuit microstrip stubs 92 that may be switched in and out of the circuit. The stubs 92 may have different lengths that provide different reactance amounts. The second exemplified element 90 has twelve stubs 92, but the invention is not so limited. Each stub 92 comprises a switch 93, which in this embodiment is a PIN diode 93 whose cathode is coupled (e.g., by ribbon bonding) to a central microstrip 91. At nodes 94, each stub 92 is coupled to a driver circuit (not shown) that can forward or reverse bias the diode 93 to turn the diode 93 ON or OFF, and thus switch the corresponding stub 92 in or out of the circuit to enable the first variable network element 90 to provide varying total reactances. An RF filter may be coupled between each diode 93 and the central microstrip 91.

The central microstrip 91 comprises a first section 96, a second section 97, and a fixed series element 98 connected in series between the first section 96 and the second section 97. The stubs 92 are arranged as a first group 99, comprising six stubs 92, each having its corresponding switch 93 coupled to the first section 96 of the central microstrip 91; and a second group 100, comprising six stubs 92, each having its corresponding switch 93 coupled to the second section 97 of the central microstrip 91. The stubs 92 may be arranged in pairs, one on either side of the central microstrip 91. This may help to minimize the required length of the central microstrip 91. Within each group 99, 100, a pair of stubs may be separated from an adjacent pair of stubs by a length of the central microstrip 91 sufficient to provide a 180 degree phase separation between adjacent pairs of stubs, which allows for the shunt reactance presented by each discrete stub to add in effect. However, the present invention is not limited thereto; the length of the central microstrip 91 separating adjacent pairs of stubs may be sufficient to provide a 90 degree or 45 degree phase separation.

The fixed series element 98 may be a transmission line with an impedance of 50 Ohms, the length of which determines the separation between the two groups 99, 100 of stubs. The length may be chosen to provide a phase difference of 90 degrees between an input of the fixed series element 98, to which the first section is coupled, and an output of the fixed series element 98, to which the second section is coupled. The fixed series element 98 may be a transmission line with an impedance of less than 50 Ohms, which may provide an increased bandwidth. This may be particularly useful in applications wherein the frequency of the signal input to the variable network element 90 may deviate from an expected value.

The second variable network element 90 may provide improved performance as compared with the first variable network element 80. By providing two groups of stubs separated by the fixed series element, a larger impedance matching region with an acceptable Q factor at microwave frequencies can be provided as compared with the first variable network element 80.

### Compensating for Parameter Discrepancy

Multi-feed electrode reaction plasma chambers for semiconductor processing applications, such as plasma chamber 19 in FIG. 1, benefit from accurate, repeatable, and uniform power delivery. These multi-feed systems can be employed when microwave energy is used for plasma excitation. Multiple electrodes are used to create a uniform plasma density across the surface of the wafer since the wafer can be greater than a wavelength at microwave frequencies. A uniform plasma density is directly related to a uniform deposition on the wafer. Uniform deposition leads to uniform die on the wafer and higher yields.

As discussed above with regard to FIG. 1, multi-feed systems can employ multiple matching circuits. Each individual feed 12 can have its own matching circuit 11. Matching circuits are designed to vary the impedance transformation from input to output. The power sources in these applications are typically designed to deliver maximum power into a 50 Ohm, non-reactive load. But the plasma chamber impedance is rarely 50 Ohms. The reactive portion of the chamber impedance can be inductive or capacitive and the real part of the chamber load impedance can be greater than or lower than 50 Ohms. So a matching circuit is needed for maximum power delivery. Furthermore, the chamber impedance can be different for each individual feed. So even though each matching circuit may be very similar, the impedance transformation for each feed may be different.

As discussed in co-owned application U.S. Pat. No. 18,673,736, which is incorporated herein by reference in its entirety, a mode converter may be used to provide the electromagnetic wave to the plasma chamber. The mode converter accepts a coaxial input and converts this to an electromagnetic wave guide launch. As the sinusoidal voltage of the feed varies, the resultant e-field in the chamber from all the various feeds will have constructive and destructive interference. Since it is desirable to have a uniform field to get a uniform plasma, the goal is to have the peaks and valleys of the distributed field average out.

### Compensation for Power Loss

The absolute power of each individual feed into the plasma chamber directly impacts the electric field (e-field) distribution in the chamber. Depending on the power and phase of each feed, the plasma e-field can be uniform, rotating, or non-uniform.

The matching circuits can be tuned for different impedance transformations. Matching circuits have a variable loss depending on their position. For example, referring to FIG. 4, each switch 61 (e.g., PIN diode) that is switching in a discrete element 55 at a given match position may cause a power loss. As a result, the more switches 61 that are switching in a discrete element 55, the lossier the matching circuit will be, and different match positions will have different power losses from the input to the output of the matching circuit. This loss can be measured on a network analyzer and the loss can be stored (e.g., in a table) for each match position. It is important to maintain a desired power output from each feed. So the power of the excitation sources for each feed need to be adjusted to compensate for the power losses through the RF power delivery system.

It is desirable to characterize the loss of each matching circuit at each possible matching position. This characterization can be done, for example, during production testing. The loss can be stored in memory. During operation, the amplitude of the power source can be adjusted to compensate for the anticipated power loss. Since the exact position is known for each match at any time, the power loss can then be looked up from the characterization table in memory. As a result, the relative power of the individual feeds into the chamber can still be maintained.

Referring to FIG. 1, according to one embodiment, a memory 41 is configured to store, for each match position of each of the matching circuits 11, and for each of the output signals S1-S6, parameter discrepancy data for a parameter of the output signal. In this embodiment, the parameter is a power of the output signal. In other embodiments, the parameter may be a parameter related to a power or a phase of the output signal at an output 17 of the matching circuit 11 or at an input 18 of the plasma chamber 19.

The parameter discrepancy data may be any data related to or indicative of an anticipated discrepancy between a desired value for the parameter and an actual value of the parameter. In this embodiment, it would be data related to a desired power and an actual power for a given feed at a given match position, but the invention is not so limited. For example, the parameter discrepancy data may be, for each match position of each of the matching circuits, and for each of the output signals, a difference between the desired value for the parameter and the actual value for the parameter. The parameter discrepancy data may also be, for each match position of each of the matching circuits, and for each of the output signals, a value based on a difference between the desired value for the parameter and the actual value for the parameter. The parameter discrepancy data may also be, for each match position of each of the matching circuits, and for each of the output signals, related to a power setting or a phase setting for the power source.

Referring again to FIG. 1, a control circuit 45 is configured to, for each of the matching circuits 11 and its corresponding one of the output signals S1-S6, during operation of the system, determine a current match position for the matching circuit 11. The control circuit 45 is further configured to, for each of the matching circuits and its corresponding one of the output signals, cause the power source, during operation of the system, to alter the parameter of the output signal based on the parameter discrepancy data for the match position corresponding with the current match position for the matching circuit. The alteration of the parameter of the output signal is directed to preventing or decreasing the anticipated discrepancy between the desired value for the parameter and the actual value for the parameter. For example, the control circuit's alteration of the output signal may comprise the power source increasing a power of the transmitted output signal to compensate for power loss caused by the matching circuit.

### Compensating for Phase Shifting

The relative phase of each individual feed into the plasma chamber also directly impacts the e-field distribution in the chamber. Depending on the phase of each feed, the plasma e-field can be uniform, rotating, or non-uniform.

As mentioned previously, the matching circuits can be tuned for different impedance transformations. As with power, the phase from the input to the output of the matching circuit will vary as the impedance transformation is adjusted. It is important to maintain a desired phase shift between each of the fields. For example, for the reasons discussed in co-owned application U.S. Pat. No. 18,673,736, which is incorporated herein by reference, in the six-feed system of FIG. 1, it is desirable to maintain a desired phase difference of 60 degrees between adjacent feeds. In other systems, the ideal phase shift may be different. To maintain the ideal phase shift, the phase of the excitation sources for each feed needs to be adjusted to compensate for the phase shifts through the RF power delivery system.

It is desirable to measure the relative phase of each feed as close to the chamber as possible (e.g., the phase may be measured or calculated at the output of each matching circuit). The phase shift of each matching circuit can be characterized during production testing. The phase shift can be measured for each of the possible match positions. These phase shifts can be stored in memory. The phase shift of each individual amplifier can also be characterized. This can also be stored in memory of the controls for this system. During operation, the phase of the excitation source can be adjusted to compensate for these amplifier and match phase shifts. Since the exact position is known for each match at any time, the phase shift can then be looked up from the characterization table in memory. As a result, the relative phase of the individual feeds into the chamber can still be maintained.

Referring again to FIG. 1, in this embodiment, the parameter is related to a phase of the first signal at an output 17 of the matching circuit 11 or at an input 18 of the plasma chamber 19. Further, the control circuit's 45 alteration of the output signal S1 comprises the power source 47 adjusting a phase of the transmitted output signal S1 to compensate for a phase shift caused by the matching circuit 11 and/or by the amplifier, if the amplifier is separate to the matching circuit 11. Note that in yet other embodiments, the parameter discrepancy data may comprise data for both a power and a phase of the output signal S1 at the output 17 of the matching circuit 11 or at the input 18 of the plasma chamber 19.

### Parameter Matrices

In certain embodiments, for each of the matching circuits, the parameter discrepancy data may be determined based on parameter matrix data for the matching circuit. Each impedance matching circuit 11, coupled between the power source 47 and the plasma chamber 19, may be characterized by one of several types of parameter matrices known to those of skill in the art, including two-port parameter matrices. An S-parameter matrix and a Z-parameter matrix are two examples of such parameter matrices. Other examples include, but are not limited to, a Y-parameter matrix, a G-parameter matrix, an H-parameter matrix, a T-parameter matrix, and an ABCD-parameter matrix. Those of skill in the art will recognize also that these various parameter matrices may be mathematically converted from one to the other for an electrical circuit such as a matching network.

As is known in the art, the S-parameter matrix is composed of components called scatter parameters, or S-parameters for short. An S-parameter matrix for the impedance matching circuit has four S-parameters, namely S₁₁, S₁₂, S₂₁, and S₂₂, each of which represents a ratio of voltages at the input 13 and output 17 of the matching circuit 11. All four of the S-parameters for the impedance matching circuit are determined and/or calculated in advance, so that the full S-parameter matrix is known. The parameters of the other types of parameter matrices may be similarly determined and/or calculated in advance and incorporated into the parameter matrix. For example, a Z-parameter matrix for the impedance matching circuit has four Z-parameters, namely Z₁₁, Z₁₂, Z₂₁, and Z₂₂.

By compiling the parameter lookup table in this manner, the entire time cost of certain calculations occurs during the testing phase for the RF matching network, and not during actual use of the RF matching network 11 with a plasma chamber 19. Moreover, because locating a value in a lookup table can take less time than calculating that same value in real time, using the lookup table can aid in reducing the overall time needed to achieve an impedance match. In a plasma deposition or etching process which includes potentially hundreds or thousands of impedance matching adjustments throughout the process, this time saving can help add directly to cost savings for the overall fabrication process. The discussion of parameter matrices in co-owned U.S. Pub. No. 2023/0215696 is incorporated herein by reference in its entirety.

Alternatively, rather than the S-map data, the prediction can be obtained using direct measurements, using hardware to measure the phase shift. In these embodiments, the parameter discrepancy data is determined based on sensing an output value for the parameter at the output of the matching circuit and comparing the output value to an input value for the parameter at the input of the matching circuit. One approach is to measure the phase at the output of each matching circuit and compare it to the phase at the input of the same matching circuit. This phase shift can then be used to determine the amount of phase shift is required at the source. Another approach is to measure the phase at the output of the matching circuit and compare it to the signal source. This would determine the total phase shift for each individual feed path. This information could then be used to determine the phase shift for each feed.

### Control Schemes

As described above, there are multiple variables that need to be adjusted for each feed of the multi-feed system. Each path may have a directional coupler (or a voltage, current, and phase sensor) in the amplifier. It could also have a phase sensor at the input and/or output of each match. Each match can have tens of thousands of positions. Each feed can have a 0-180-degree phase shift and amplitude control from 0 to full power.

Various methods can be used to tune this complex system. The goal is to reach a stable position as quick as possible and stay there throughout the entire process. The first method of control is to operate all channels of the multi-feed independently and simultaneously, and thus to alter the parameters of each of the signals independently and simultaneously. In this scenario, power can be applied to the process chamber based on a predetermined RF setpoint. Each match can be tuned to the ideal match position individually, each control loop cycle based on feedback from its V, I, and P (phase) sensor. The relative phase and amplitude of each feed can be adjusted each control loop cycle as the match position is adjusted. The phase and amplitudes will be adjusted for the reasons stated above. Naturally, since there is cross talk between each individual feed, the sequential tuning of each channel can result in the previously tuned channels becoming detuned again. So this process can be iterated each control loop until an ideal condition is reached. This process could take some time to reach an ideal matched condition where the phase and amplitude of each channel are at the most ideal condition.

Measuring V and I accurately at microwave frequencies can be challenging. In some embodiments, instead of measurements of V, I, and phase, the control loop cycle may be based on feedback from a gamma sensor providing a reflection parameter value and phase value, for example a reflected power value and phase value. More specifically, the reflection parameter value is a reflection coefficient value (sometimes referred to as “gamma”), which represents the ratio of the amplitude of a reflected wave to an incident wave.

Another approach is to only turn on one channel of the multi-feed system at a time, strike the plasma and tune the match. Then each of the other feeds could be turned on with the same match position as the first. The phases could be set based on the phase recorded in memory and the ideal phase shift required between channels for a uniform plasma. The pre- and post-strike impedances of the plasma can be quite different so using this approach will minimize the number of tuning steps for all the feeds except the one that struck the plasma. The others are tuned to the post strike impedance. According to this approach, the control circuit can alter the parameter of one of the output signals while the other output signals are off, and subsequently turns on the other output signals and alters the parameters of the other output signals.

Another approach is to assume all of the multi-feed paths are the same and use the sensor feedback from only one of the feeds to then set the match position, amplitude, and phase of all the other feeds. Then once the system is close to an ideal condition, the sensor feedback from each individual feed could be used to fine tune each feed for the best uniformity.

In another embodiment, the power discrepancy data is derived from a machine learning algorithm that has been trained by historical data for the parameter during operation.

### Method of Providing Energy to a Plasma Chamber having Multiple Power Signal Inputs

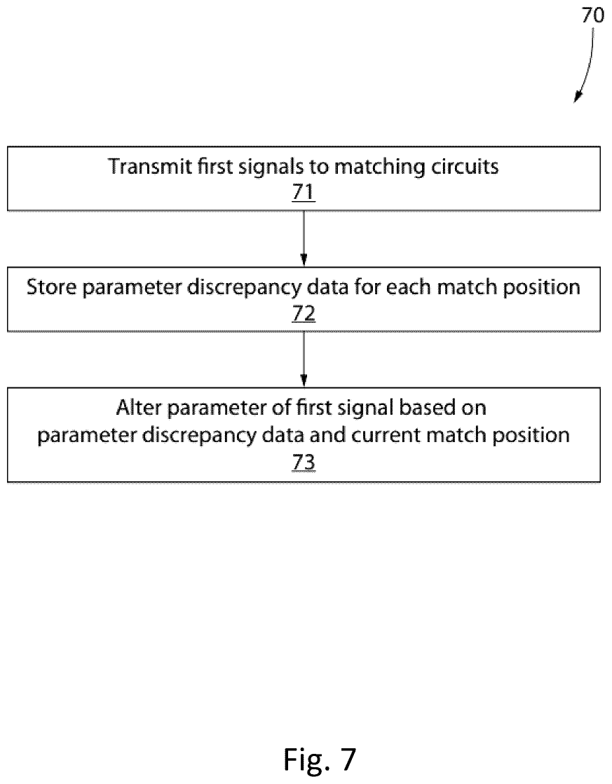

Finally, referring to FIG. 7, in another aspect, the invention may be understood as a method 70 of providing energy to a plasma chamber having multiple power signal inputs, the method comprising the following steps. In a first operation 71, output signals are transmitted to matching circuits such that each of the matching circuits receives a single corresponding one of the output signals. Each of the matching circuits comprises at least one variable network element, each variable network element has different configurations providing different match positions, and each of the matching circuits is configured to couple to a plasma chamber. In operation 72, the method 70 stores, for each match position of each of the matching circuits, and for each of the output signals, parameter discrepancy data for a parameter of the output signal. The parameter is related to a power or a phase of the output signal at an output of the matching circuit or at an input of the plasma chamber. The parameter discrepancy data is related to an anticipated discrepancy between a desired value for the parameter and an actual value of the parameter. In operation 73, for each of the matching circuits and its corresponding one of the output signals, the method 70 causes the power source, during operation of the system, to alter the parameter of the output signal based on the parameter discrepancy data for the match position corresponding with a current match position for the matching circuit. The alteration of the parameter of the output signal is directed to preventing or decreasing the anticipated discrepancy between the desired value for the parameter and the actual value for the parameter.

While the inventions have been described with respect to specific examples including presently preferred modes of carrying out the inventions, those skilled in the art will appreciate that there are numerous variations and permutations of the above-described systems and techniques. It is to be understood that other embodiments may be utilized and structural and functional modifications may be made without departing from the scope of the present inventions. Thus, the spirit and scope of the inventions should be construed broadly as set forth in the appended claims.

What is claimed is:

1. A system, comprising:
a power source transmitting output signals via power source outputs;
matching circuits coupled to the power source outputs, each matching circuit:
configured to receive a single corresponding output signal of the output signals;
comprising at least one variable network element, each variable network element having different configurations providing different match positions; and
configured to couple to a plasma chamber;
a memory configured to store, for each match position of each matching circuit, and for each output signal, parameter discrepancy data for a parameter of the output signal;
wherein the parameter is related to a power or a phase of the output signal at an output of the matching circuit or at an input of the plasma chamber; and
wherein the parameter discrepancy data is related to an anticipated discrepancy between a desired value for the parameter and an actual value of the parameter; and
a control circuit configured to, for each matching circuit and its corresponding output signal, cause the power source to alter the parameter of the output signal based on the parameter discrepancy data for the match position corresponding with a current match position for the matching circuit, the alteration of the parameter of the output signal directed to preventing or decreasing the anticipated discrepancy between the desired value for the parameter and the actual value for the parameter.

2. The system of claim 1, wherein the parameter discrepancy data is, for each match position of each matching circuit, and for each output signal, a difference between the desired value for the parameter and the actual value for the parameter.

3. The system of claim 1, wherein the parameter discrepancy data is, for each match position of each matching circuit, and for each output signal, a value based on a difference between the desired value for the parameter and the actual value for the parameter.

4. The system of claim 1, wherein the parameter discrepancy data is, for each match position of each matching circuit, and for each output signal, related to a power setting or a phase setting for the power source.

5. The system of claim 1:
wherein the parameter is a power of the output signal; and
wherein the control circuit's alteration of the output signal comprises the power source increasing a power of the transmitted output signal to compensate for power loss caused by the matching circuit.

6. The system of claim 1:
wherein the parameter is a phase of the output signal; and
wherein the control circuit's alteration of the output signal comprises the power source adjusting a phase of the transmitted output signal to compensate for a phase shift caused by the matching circuit.

7. The system of claim 1, wherein the parameter discrepancy data comprises data for both a power and a phase of the output signal at the output of the matching circuit or at the input of the plasma chamber.

8. The system of claim 1, wherein each variable network element comprises a plurality of discrete reactance elements capable of being switched in and out of the matching circuit by a corresponding switch to provide different reactances.

9. The system of claim 8, wherein the discrete reactance elements comprise microstrips.

10. The system of claim 9, wherein each matching circuit comprises a central microstrip comprising a first section to which a first group of stubs are each coupled; a second section to which a second group of stubs are each coupled; and a fixed series element coupled between the first section and the second section.

11. The system of claim 10, wherein the fixed series element is configured so as to provide a 90 degree phase difference between its input and its output.

12. The system of claim 10, wherein adjacent stubs in each group of stubs are separated by a length of microstrip configured to provide a 180 degree phase difference between adjacent stubs.

13. The system of claim 1, wherein the control circuit alters the parameter of only one of the output signals while the other output signals are off, and subsequently turns on the other output signals and alters the parameters of the other output signals.

14. The system of claim 1, wherein the parameter discrepancy data is derived from a machine learning algorithm that has been trained by historical data for the parameter.

15. A method of providing energy to a plasma chamber having multiple power signal inputs, the method comprising:
transmitting output signals, using a power source, to matching circuits such that each matching circuit receives a single corresponding output signal of the output signals;
wherein each of the matching circuits comprises at least one variable network element, each variable network element having different configurations providing different match positions, and
coupling each matching circuit to the plasma chamber;
storing, for each match position of each matching circuit, and for each output signal, parameter discrepancy data for a parameter of the output signal;
wherein the parameter is related to a power or a phase of the output signal at an output of the matching circuit or at an input of the plasma chamber; and
wherein the parameter discrepancy data is related to an anticipated discrepancy between a desired value for the parameter and an actual value of the parameter; and
for each matching circuit and its corresponding output signal, causing the power source, during operation of the system, to alter the parameter of the output signal based on the parameter discrepancy data for the match position corresponding with a current match position for the matching circuit, the alteration of the parameter of the output signal directed to preventing or decreasing the anticipated discrepancy between the desired value for the parameter and the actual value for the parameter.

16. The method of claim 15 wherein the parameter discrepancy data is, for each match position of each matching circuit, and for each output signal, a value based on a difference between the desired value for the parameter and the actual value for the parameter.

17. The method of claim 15 wherein the parameter discrepancy data is, for each match position of each matching circuit, and for each output signal, related to a power setting or a phase setting for the power source.

18. A system, comprising:
matching circuits configured to couple to a power source, each matching circuit:
configured to receive a corresponding output signal from the power source;
comprising at least one variable network element, each variable network element having different configurations providing different match positions; and
configured to couple to a plasma chamber;
a memory configured to store, for each match position of each matching circuit, and for each output signal, parameter discrepancy data for a parameter of the output signal;
wherein the parameter is related to a power or a phase of the output signal at an output of the matching circuit or at an input of the plasma chamber; and
wherein the parameter discrepancy data is a value based on a difference between a desired value for the parameter and an actual value for the parameter; and
a control circuit configured to, for each matching circuit and its corresponding output signal, cause the power source to alter the parameter of the output signal based on the parameter discrepancy data for the match position corresponding with a current match position for the matching circuit, the alteration of the parameter of the output signal directed to preventing or decreasing the anticipated discrepancy between the desired value for the parameter and the actual value for the parameter.

19. The system of claim 18:
wherein the parameter is a power of the output signal; and
wherein the control circuit's alteration of the output signal comprises the power source increasing a power of the transmitted output signal to compensate for power loss caused by the matching circuit.

20. The system of claim 18:
wherein the parameter is a phase of the output signal; and
wherein the control circuit's alteration of the output signal comprises the power source adjusting a phase of the transmitted output signal to compensate for a phase shift caused by the matching circuit.
